(19) United States
(12) Patent Application Publication
(10) Pub. No.: US 2026/0040780 A1
(43) Pub. Date: Feb. 5, 2026

(54) ELECTRO-OPTICAL DEVICE AND ELECTRONIC APPARATUS

(71) Applicant: SEIKO EPSON CORPORATION, Tokyo (JP)

(72) Inventor: Hitoshi OTA, SHIOJIRI-SHI (JP)

(73) Assignee: SEIKO EPSON CORPORATION, Tokyo (JP)

(21) Appl. No.: 18/619,176

(22) Filed: Mar. 28, 2024

(30) Foreign Application Priority Data
Mar. 29, 2023 (JP) 2023-053142

(51) Int. Cl. H10K 59/131; H10K 59/35; H10K 59/80

(52) U.S. Cl. CPC H10K 59/131; H10K 59/876; H10K 59/35

(57) ABSTRACT

An electro-optical device includes a substrate, a first electrode, a second electrode, a third electrode, a first reflection layer, a second reflection layer, a light emission function layer, a first optical adjustment layer, a second optical adjustment layer, a first driving circuit, a second driving circuit, a first conductive portion being in contact with the second electrode at a first position in a normal line direction of the substrate and being configured to electrically couple the second electrode and the first reflection layer, and a second conductive portion being in contact with the third electrode at a second position in the normal line direction and being configured to electrically couple the third electrode and the second reflection layer.

The present application is based on, and claims priority from JP Application Serial Number 2023-053142, filed Mar. 29, 2023, the disclosure of which is hereby incorporated by reference herein in its entirety.

### BACKGROUND

### 1. Technical Field

The present disclosure relates to an electro-optical device and an electronic apparatus.

### 2. Related Art

There has been known an electro-optical device such as a liquid crystal display device and an organic electroluminescent display device. One example of such a device is a display device described in JP-A-2022-54048.

The display device in JP-A-2022-54048 includes a substrate, an insulating layer, a plurality of reflection plates, a plurality of first electrodes, an electroluminescent layer, and a second electrode. A driving circuit including a plurality of thin film transistors is provided at the substrate. The plurality of first electrodes are provided at the insulating layer, and are arranged two-dimensionally in a matrix form. The first electrode includes a first surface and a second surface. The plurality of reflection plates are provided to face the second surfaces of the plurality of first electrodes, respectively. The second electrode is provided to face the first surfaces of the plurality of first electrodes. The electroluminescent layer is provided between the plurality of first electrodes and the second electrode.

In such a display device, a plurality of resonator structures that resonate output light from the electroluminescent layer are configured by the plurality of reflection plates and the second electrode. Further, an optical adjustment layer is provided between the plurality of reflection plates and the plurality of first electrodes. The thickness of the optical adjustment layer differs for a sub pixel of each color, and an optical path length in each of the resonator structures is adjusted by the optical adjustment layer. Further, in JP-A-2022-54048, the thin film transistor of each of the driving circuits provided at the substrate is electrically coupled to the first electrode via a contact plug.

The thickness of the optical adjustment layer differs. Consequently, the distance between the thin film transistor and the first electrode differs for a sub pixel of each color. Therefore, an aspect ratio of the contact plug also differs for a sub pixel of each color. Thus, for example, a step is disadvantageously generated between an upper surface of a contact corresponding to a certain color and an upper surface of a contact corresponding to another color. When light hits such a step due to the contacts, stray light is disadvantageously generated, and display quality of the electro-optical device may be degraded.

### SUMMARY

In order to solve the above-mentioned problem, an electro-optical device according to a preferred embodiment of the present disclosure includes a substrate, a first electrode having a semi-transmissive property, a second electrode having a light transmissive property, being provided between the first electrode and the substrate, and facing the first electrode, a third electrode having a light transmissive property, being provided between the first electrode and the substrate, and facing the first electrode, a first reflection layer being provided between the substrate and the second electrode and facing the second electrode, a second reflection layer being provided between the substrate and the third electrode and facing the third electrode, a light emission function layer being provided between the first electrode and the second electrode and between the first electrode and the third electrode, a first optical adjustment layer being provided between the second electrode and the first reflection layer, a second optical adjustment layer being provided between the third electrode and the second reflection layer, a first driving circuit being provided at the substrate and being configured to control a current amount supplied to the second electrode, a second driving circuit being provided at the substrate and being configured to control a current amount supplied to the third electrode, a first conductive portion being in contact with the second electrode at a first position of the substrate in a normal line direction and being configured to electrically couple the second electrode and the first reflection layer, and a second conductive portion being in contact with the third electrode at a second position in the normal line direction and being configured to electrically couple the third electrode and the second reflection layer, wherein the second electrode includes a first light emission region through which light in a first wavelength range passes, the third electrode includes a second light emission region through which light in a second wavelength range passes, a first distance is larger than a second distance, and a difference between a third distance and a fourth distance is smaller than a difference between the first distance and the second distance, the first distance being a distance between the first light emission region of the second electrode and the first reflection layer in the normal line direction, the second distance being a distance between the second light emission region of the third electrode and the second reflection layer in the normal line direction, the third distance being a distance between the first reflection layer and the first position in the normal line direction, the fourth distance being a distance between the second reflection layer and the second position in the normal line direction.

### BRIEF DESCRIPTION OF THE DRAWINGS

FIG. 1 is a plan view illustrating an electro-optical device according to an embodiment.

FIG. 2 is an equivalent circuit diagram of a sub pixel in FIG. 1.

FIG. 3 is a plan view of one pixel of the electro-optical device in FIG. 1.

FIG. 4 is a cross-sectional view illustrating the electro-optical device in FIG. 1.

FIG. 5 is a view illustrating a part of the electro-optical device in FIG. 4.

FIG. 6 is a plan view of one pixel in a first modification example.

FIG. 7 is a plan view of one pixel in a second modification example.

FIG. 8 is a plan view of one pixel in a third modification example.

FIG. 9 is a plan view of one pixel in a fourth modification example.

FIG. 10 is a plan view schematically illustrating a part of a virtual image electro-optical device as an example of an electronic apparatus.

FIG. 11 is a perspective view illustrating a personal computer as an example of an electronic apparatus.

### DESCRIPTION OF EMBODIMENTS

A preferred embodiment according to the present disclosure is described below with reference to the accompanying drawings. In addition, in the drawings, dimensions and scales of each part are appropriately made different from actual ones, and some parts are shown schematically to make them easier to understand. Also, the scope of the present disclosure is not limited to these forms unless the present disclosure is specifically described as being limited in the following description.

Further, “electrical coupling” between the element α and the element β includes not only a configuration where the element α and the element β conduct by being directly joined to each other, but also a configuration where the element α and the element β indirectly conduct through another conductive material. Further, “the element β at the element α” includes not only a configuration where the element α and the element β are in direct contact with each other, but also a configuration where the element α and the element β are in indirect contact with each other through another conductive material. Further, “the element α is equivalent to the element β” indicates substantial equivalence, and includes a manufacturing error and the like. Further, “a difference between the element α and the element β” indicates an absolute value of the difference.

### 1. Embodiment

### 1A. Basic Configuration of Electro-Optical Device

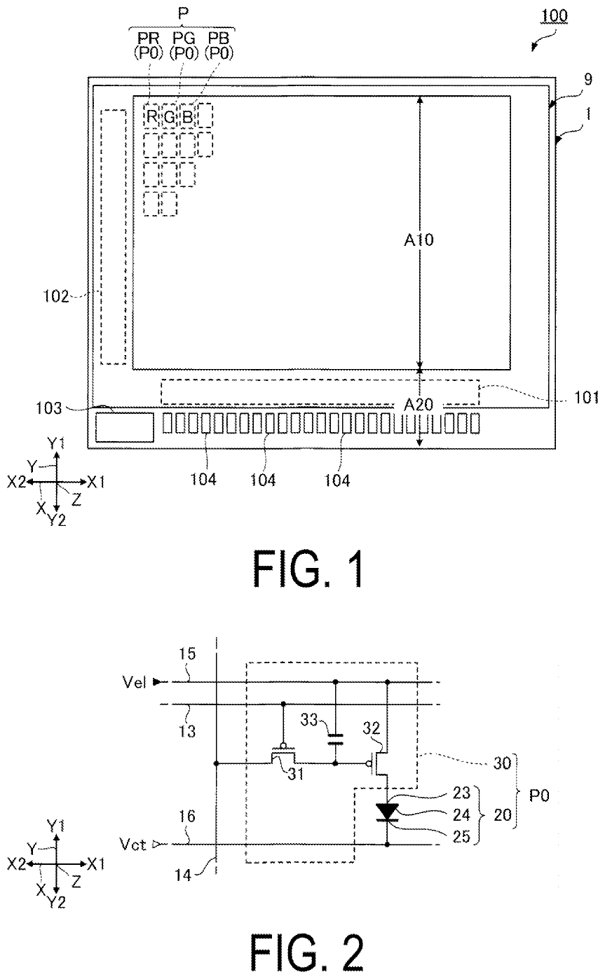

FIG. 1 is a plan view illustrating an electro-optical device 100 according to an embodiment. Hereinafter, for convenience of description, description is made while using an X-axis, a Y-axis, and a Z-axis orthogonal to one another as appropriate. In addition, one direction along the X axis is defined as an X1 direction, and a direction opposite to the X1 direction is defined as an X2 direction. Similarly, one direction along the Y axis is defined as a Y1 direction, and a direction opposite to the Y1 direction is defined as a Y2 direction. One direction along the Z axis is defined as a Z1 direction, and a direction opposite to the Z1 direction is defined as a Z2 direction. Further, viewing in the Z1 direction or the Z2 direction is referred to as “plan view”. Further, a “light transmissive property” indicates transmissivity with respect to visible light, and indicates a transmittance of visible light of 50% or more. Further, a “light-reflecting property” indicates reflectivity to visible light, and indicates that a reflectance of visible light may be greater than or equal to 50%.

Further, in the embodiment described below, a pixel electrode 23R corresponds to a “second electrode”. A pixel electrode 23G corresponds to a “third electrode”. A pixel electrode 23B corresponds to a “fourth electrode”. A reflection layer 21R corresponds to a “first reflection layer”. A reflection layer 21G corresponds to a “second reflection layer”. A reflection layer 21B corresponds to a “third reflection layer”. An optical adjustment layer 22R corresponds to a “first optical adjustment layer”. An optical adjustment layer 22G corresponds to a “second optical adjustment layer”. An optical adjustment layer 22B corresponds to a “third optical adjustment layer”. A driving circuit 30R corresponds to a “first driving circuit”. A driving circuit 30G corresponds to a “second driving circuit”. A driving circuit 30B corresponds to a “third driving circuit”. A conductive portion 4R corresponds to a “first conductive portion”. A conductive portion 4G corresponds to a “second conductive portion”. A conductive portion 4B corresponds to a “third conductive portion”. A light emission region AR corresponds to a “first light emission region”. A light emission region AG corresponds to a “second light emission region”. A light emission region AB corresponds to a “third light emission region”. A position P1 corresponds to a “first position”. A position P2 corresponds to a “second position”. A position P3 corresponds to a “third position”. A distance D1 corresponds to a “first distance”. A distance D2 corresponds to a “second distance”. A distance D3 corresponds to a “third distance”. A distance D4 corresponds to a “fourth distance”. A distance D5 corresponds to a “fifth distance”. A distance D6 corresponds to a “sixth distance”. Further, a normal line direction A1 of a substrate 10 matches with the Z1 direction. The X1 direction is an example of a “first direction”, and intersects the normal line direction A1. The Y2 direction is an example of a “second direction”, and intersects the normal line direction A1 and the X1 direction.

The electro-optical device 100 illustrated in FIG. 1 is an organic electroluminescence (EL) device that displays a full color image, for example. For example, the electro-optical device 100 can be used as a flexible display. Note that, the images include those only displaying text information. The electro-optical device 100 is suitably used as a micro display configured to display an image in a head-mounted display, for example.

The electro-optical device 100 includes a display region A10 and a peripheral region A20. The display region A10 is a region that displays an image. The shape of the display region A10 in plan view is a substantially rectangular shape, but may be another shape. The peripheral region A20 is provided outside of the display region A10, and is a frame-like region that surrounds the display region A10 in plan view.

The display region A10 includes a plurality of pixels P. Each of the pixels P is a minimum unit for displaying an image. The plurality of pixels P are arranged in a matrix along the X axis and the Y axis, for example. Each of the pixels P includes a sub pixel PB, a sub pixel PG, and a sub pixel PR. The sub pixel PR emits light in a red wavelength range. The sub pixel PG emits light in a green wavelength range. The sub pixel PB emits light in a blue wavelength range. The red wavelength range is an example of a “first wavelength range” that exceeds 580 nm and is 700 nm or less. The green wavelength range is an example of a “second wavelength range” that exceeds 500 nm and is 580 nm or less. The blue wavelength range is an example of a “third wavelength range” that exceeds 400 nm and is 500 nm or less.

In the following description, when the sub pixel PR, the sub pixel PG, and the sub pixel PB are not distinguished from each other, they are expressed as a sub pixel P0. The sub pixel P0 is a constituent element of the pixel P. The sub pixel P0 is a minimum unit of a displayed image. One pixel P of a color image is expressed by the sub pixel PR, the sub pixel PG, and the sub pixel PB. The sub pixel P0 is controlled independently from other sub pixels P0. In the present embodiment, arrangement of the sub pixel P0 is stripe arrangement.

As illustrated in FIG. 1, the electro-optical device 100 includes an element substrate 1 and a light-transmitting substrate 9. The electro-optical device 100 has a co-called top emission structure. The electro-optical device 100 causes the light-transmitting substrate 9 to emit light.

In the peripheral region A20, a data line driving circuit 101, a scanning line driving circuit 102, a control circuit 103, and a plurality of external terminals 104 are arranged. The data line driving circuit 101 and the scanning line driving circuit 102 control each component included in each of the sub pixels P0. Image data is supplied to the control circuit 103 from a higher-level circuit omitted in illustration. The control circuit 103 supplies various signals based on the image data to the data line driving circuit 101 and the scanning line driving circuit 102 to control display of an image. Although omitted in illustration, the external terminals 104 are coupled to a flexible printed circuit (FPC) board or the like for electrical coupling with a higher-level circuit. Note that a power supply circuit, which is omitted in illustration, is electrically coupled to the electro-optical device 100.

### 1B. Electrical Configuration of Electro-Optical Device

FIG. 2 is an equivalent circuit diagram of the sub pixel P0 illustrated in FIG. 1. The electro-optical device 100 includes a plurality of scanning lines 13 and a plurality of data lines 14. In FIG. 2, one scanning line 13 and one data line 14 that correspond to one sub pixel P0 are illustrated. The scanning lines 13 extend along the X-axis, and the data lines 14 extend along the Y-axis. Note that, although omitted in illustration, the plurality of scanning lines 13 and the plurality of data lines 14 are arranged in a lattice form. Further, each of the scanning lines 13 is coupled to the scanning line driving circuit 102 illustrated in FIG. 1, and each of the data lines 14 is coupled to the data line driving circuit 101 illustrated in FIG. 1.

As illustrated in FIG. 2, the sub pixel P0 includes a light-emitting element 20 and a driving circuit 30. The light-emitting element 20 is constituted by an organic light-emitting diode (OLED). The light-emitting element 20 includes the pixel electrode 23, a first electrode 25, and a light emission function layer 24. The pixel electrode 23 is provided for each of the sub pixels P0, and functions as an anode. The first electrode 25 is commonly shared by the plurality of sub pixels P0, and functions as a cathode. The light emission function layer 24 is arranged between the pixel electrode 23 and the first electrode 25. In the light-emitting element 20, holes supplied from the pixel electrode 23 and electrons supplied from the first electrode 25 are recombined in the light emission function layer 24. Consequently, the light emission function layer 24 generates light. The first electrode 25 is electrically coupled to a power supplying line 16. A power supply potential Vct on a low potential side is supplied from the power supply circuit, which is omitted in illustration, to the power supplying line 16. The pixel electrode 23 can be set independently to be different from other pixel electrodes 23.

The driving circuit 30 is a pixel circuit that controls driving of the light-emitting element 20, and controls a current amount supplied to the pixel electrode 23. The driving circuit 30 includes a switching transistor 31, a driving transistor 32, and a retention capacitor 33. A gate of the switching transistor 31 is electrically coupled to the scanning line 13. Further, one of a source and a drain of the switching transistor 31 is electrically coupled to the data line 14, and the other is electrically coupled to a gate of the driving transistor 32. Further, one of a source and a drain of the driving transistor 32 is electrically coupled to the power supplying line 15, and the other is electrically coupled to the pixel electrode 23. Note that a potential Vel on a high potential side is supplied from the power supply circuit, which is omitted in illustration, to the power supplying line 15. Further, one of electrodes of the retention capacitor 33 is coupled to the gate of the driving transistor 32, and the other electrode is coupled to the power supplying line 15.

When the scanning line 13 is selected by activating the scanning signal by the scanning line driving circuit 102, the switching transistor 31 provided in the selected sub pixel P0 is turned on. Then, the data signal is supplied from the data line 14 to the driving transistor 32 corresponding to the selected scanning line 13. The driving transistor 32 supplies a current corresponding to a potential of the supplied data signal, that is, a current corresponding to a potential difference between the gate and the source, to the light-emitting element 20. Then, the light-emitting element 20 emits light at a luminance corresponding to a magnitude of the current supplied from the driving transistor 32. Further, when the scanning line drive circuit 102 releases the selection of the scanning line 13, and the switching transistor 31 is turned off, the potential of the gate of the driving transistor 32 is held by the retention capacitor 33. Thus, the light-emitting element 20 can emit light even after the switching transistor 31 is turned off.

Note that the configuration of the driving circuit 30 described above is not limited to the illustrated configuration. For example, the driving circuit 30 may include a transistor that controls conduction between the pixel electrode 23 and the driving transistor 32.

### 1C. Plan Arrangement of Pixel P

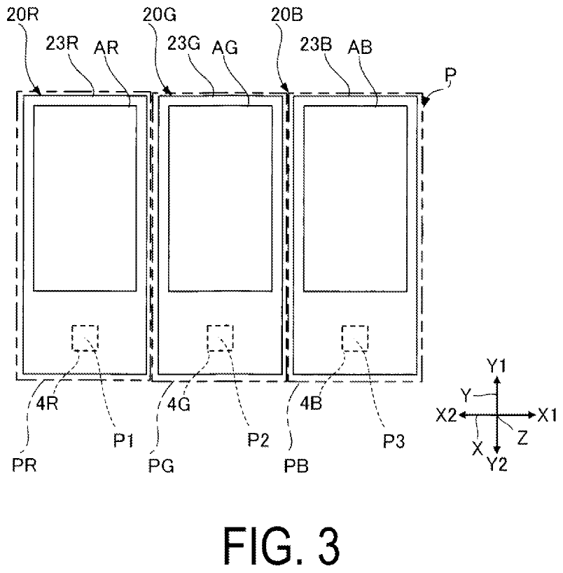

FIG. 3 is a plan view of one pixel P of the electro-optical device 100 illustrated in FIG. 1. In FIG. 3, elements of one pixel P are representatively illustrated. In the following, “R” is added to ends of reference numerals of elements related to the sub pixel PR, “G” is added to ends of reference numerals of elements related to the sub pixel PG, and “B” is added to ends of reference numerals of elements related to the sub pixel PB. Note that, when the elements are not distinguished from one another by the emission light colors, “B”, “G”, and “R” at the ends of the reference numerals are omitted.

As illustrated in FIG. 3, the element substrate 1 includes a set including the light-emitting element 20R, the light-emitting element 20G, and the light-emitting element 20B for each of the pixels P. The light-emitting element 20R is a light-emitting element 20 provided in the sub pixel PR. The light-emitting element 20G is a light-emitting element 20 provided in the sub pixel PG. The light-emitting element 20B is a light-emitting element 20 provided in the sub pixel PB.

The light-emitting element 20R is provided with the pixel electrode 23R. The pixel electrode 23R is the pixel electrode 23 provided at the sub pixel PR. The light-emitting element 20G is provided with the pixel electrode 23G. The pixel electrode 23G is the pixel electrode 23 provided at the sub pixel PG. The light-emitting element 20B is provided with the pixel electrode 23B. The pixel electrode 23B is the pixel electrode 23 provided at the sub pixel PB.

The pixel electrode 23R includes the light emission region AR. Light in a wavelength range including the red wavelength range is emitted from the light emission region AR. The conductive portion 4R described later is provided in the Y2 direction of the light emission region AR. The pixel electrode 23G includes the light emission region AG. Light in a wavelength range including the green wavelength range is emitted from the light emission region AG. The conductive portion 4G described later is provided in the Y2 direction of the light emission region AG. The pixel electrode 23B includes the light emission region AB. Light in a wavelength range including the blue wavelength range is emitted from the light emission region AB. The conductive portion 4B described later is provided in the Y2 direction of the light emission region AB.

Further, in the example illustrated in FIG. 3, a shape of each of the light emission region AR, the light emission region AG, and the light emission region AB in plan view is a rectangular shape, and may be another shape. Further, the shapes of the light emission region AR, the light emission region AG, and the light emission region AB in plan view may be different from one another, or may be the same.

### 1D. Cross-Sectional Structure in Pixel P

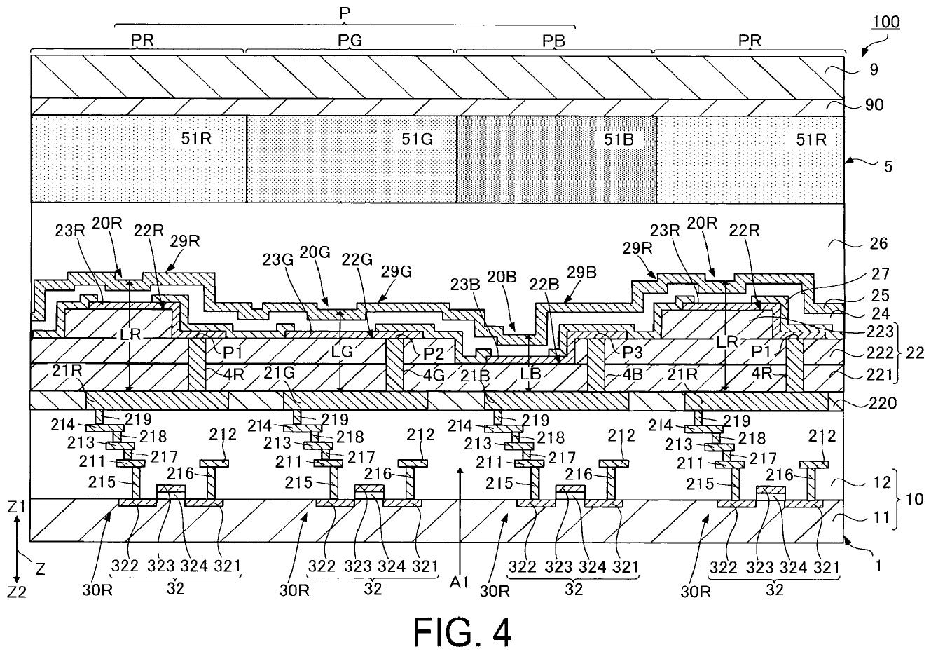

FIG. 4 is a cross-sectional view of the electro-optical device 100 in FIG. 1. Note that, in FIG. 4, elements of each of the sub pixels PB, PG, and PR are illustrated in one cross section for convenience of description.

As illustrated in FIG. 4, the electro-optical device 100 includes the element substrate 1, an adhesive layer 90, and the light-transmitting substrate 9. The element substrate 1 includes the substrate 10, and the reflection layer 21R, and the reflection layer 21G, and the reflection layer 21B, and an optical adjustment unit 22, and the pixel electrode 23R, and the pixel electrode 23G, and the pixel electrode 23B, and the light emission function layer 24, and the first electrode 25, and a sealing layer 26, and an element separation layer 27, and a coloring layer 5.

The substrate 10 is provided with the driving circuit 30 described above. The driving circuit 30 provided at the sub pixel PR is the driving circuit 30R, and controls a current amount supplied to the pixel electrode 23R. The driving circuit 30 provided at the sub pixel PG is the driving circuit 30G, and controls a current amount supplied to the pixel electrode 23G. The driving circuit 30 provided at the sub pixel PB is the driving circuit 30B, and controls a current amount supplied to the pixel electrode 23B.

The substrate 10 includes a base portion 11 having a flat plate-like shape and a lamination body 12. For example, the base portion 11 is a P-type silicon substrate. The base portion 11 is provided with the above-mentioned driving transistor 32 provided at each of the driving circuit 30R, the driving circuit 30G, and the driving circuit 30B.

The driving transistor 32 includes a drain-source region 321, a drain-source region 322, a gate electrode 323, and a gate insulating layer 324. Although detailed illustration is omitted, an N well is formed on the base portion 11. The potential Vel is supplied to the N well. The drain-source region 321 and the drain-source region 322 are P-type diffusion layer formed by doping the surface of the N well with ions. The gate electrode 323 is arranged at the base portion 11 via the gate insulating layer 324.

The lamination body 12 is arranged at the base portion 11. The lamination body 12 includes a plurality of inter-layer insulating films containing an organic material containing silicon such as silicon oxide. Relay electrodes 211, 212, 213, and 214 are arranged between the plurality of inter-layer insulating films. The relay electrode 211 is electrically coupled to the drain-source region 322 via a conductive coupling portion 215. The relay electrode 212 is electrically coupled to drain-source region 321 via a conductive coupling portion 216. The relay electrode 213 is electrically coupled to the relay electrode 211 via a conductive coupling portion 217. The relay electrode 214 is electrically coupled to the relay electrode 213 via a conductive coupling portion 218. Further, a conductive coupling portion 219 is electrically coupled to the relay electrode 214.

Note that each of the relay electrodes 211 to 214 may contain metal such as aluminum or a metal compound such as titanium nitride, and may be constituted by a single layer or a plurality of layers. Further, each of the coupling portion 215 to 219 may be a trench-type electrode formed along an inner wall surface of a contact hole being a hole passing through the inter-layer insulating film, or may be a contact plug filling the hole. For example, each of the coupling portion 215 to 218 contains metal such as tungsten (W), titanium (Ti), chromium (Cr), iron (Fe) and aluminum, metal nitride, metal silicide, and the like. Further, although omitted in illustration, the substrate 10 is provided with the above-mentioned switching transistor 31 and various wiring lines.

The reflection layer 21R, the reflection layer 21G, and the reflection layer 21B are arranged at the substrate 10 for each of the pixels P. The reflection layer 21R is provided in the sub pixel PR. The reflection layer 21R is provided between the substrate 10 and the pixel electrode 23R, and faces the pixel electrode 23R. The reflection layer 21G is provided in the sub pixel PG. The reflection layer 21G is provided between the substrate 10 and the pixel electrode 23G, and faces the pixel electrode 23G. The reflection layer 21B is provided in the sub pixel PB. The reflection layer 21B is provided between the substrate 10 and the pixel electrode 23B, and faces the pixel electrode 23B.

Each of the reflection layer 21R, the reflection layer 21G, and the reflection layer 21B is electrically coupled to the corresponding relay electrode 214 via the coupling portion 219. Each of the reflection layer 21R, the reflection layer 21G, and the reflection layer 21B has a light-reflecting property, and reflects light generated in the light emission function layer 24.

Examples of the material of each of the reflection layer 21R, the reflection layer 21G, and the reflection layer 21B include metal such as aluminum, copper (Cu), and silver (Ag) or an alloy of such metal. For example, each of the reflection layer 21R, the reflection layer 21G, and the reflection layer 21B is configured by a lamination body including an aluminum film and a titanium nitride film. The thickness of each of the reflection layer 21R, the reflection layer 21G, and the reflection layer 21B is not particularly limited, and is 100 nm or more and 200 nm or less, for example.

The reflection layer 21R, the reflection layer 21G, and the reflection layer 21B are arranged away from each other, and an embedded portion 220 is arranged to fill the gap therebetween. The embedded portion 220 contains silicon oxide or silicon nitride, for example.

The optical adjustment unit 22 is arranged at the reflection layer 21R, the reflection layer 21G, and the reflection layer 21B. The optical adjustment unit 22 includes adjustment layers 221, 222, and 223. The adjustment layer 221 is uniformly arranged in the sub pixels PR, PG, and PB. The adjustment layer 222 is arranged in the sub pixels PR and PG, and is not arranged in the sub pixel PB. The adjustment layer 223 is arranged in the sub pixel PR, and is not arranged in the sub pixels PG and PB.

Examples of the material of each of the adjustment layers 221, 222, and 223 include an inorganic silicon material such as silicon oxide and silicon nitride. Each of the thicknesses of the adjustment layers 221, 222, and 223 is 20 nm or more and 100 nm or less, for example.

Further, the optical adjustment unit 22 includes the optical adjustment layer 22R, the optical adjustment layer 22G, and the optical adjustment layer 22B. The optical adjustment layer 22R is a portion of the optical adjustment unit 22, which is provided in the sub pixel PR. The optical adjustment layer 22R is provided between the pixel electrode 23R and the reflection layer 21R. The optical adjustment layer 22G is a portion of the optical adjustment unit 22, which is provided in the sub pixel PG. The optical adjustment layer 22G is provided between the pixel electrode 23G and the reflection layer 21G. The optical adjustment layer 22B is a portion of the optical adjustment unit 22, which is provided in the sub pixel PB. The optical adjustment layer 22B is provided between the pixel electrode 23B and the reflection layer 21B.

The thickness of the optical adjustment layer 22R, the thickness of the optical adjustment layer 22G, and the thickness of the optical adjustment layer 22B are larger in the stated order. The optical adjustment layer 22R is a layer that adjusts an optical distance LR. The optical distance LR is an optical distance between the upper surface of the first electrode 25 and the upper surface of the reflection layer 21R. The optical distance LR is set to correspond to the red wavelength range. The optical adjustment layer 22G is a layer that adjusts an optical distance LG. The optical distance LG is an optical distance between the upper surface of the first electrode 25 and the upper surface of the reflection layer 21G. The optical distance LG is set to correspond to the green wavelength range. The optical adjustment layer 22B is a layer that adjusts an optical distance LB. The optical distance LB is an optical distance between the upper surface of the first electrode 25 and the upper surface of the reflection layer 21B. The optical distance LB is set to correspond to the blue wavelength range.

Further, the conductive portion 4R, the conductive portion 4G, and the conductive portion 4B are arranged in the optical adjustment unit 22 for each of the pixels P. The conductive portion 4R is a contact plug that has conductivity and fills a through hole passing through the optical adjustment layer 22R. The conductive portion 4R is in contact with the pixel electrode 23R at the position P1 of the substrate 10 in the normal line direction A1, and electrically couples the pixel electrode 23R and the reflection layer 21R to each other. The position P1 is the upper surface of the conductive portion 4R. The conductive portion 4G is a contact plug that has conductivity and fills a through hole passing through the optical adjustment layer 22G. The conductive portion 4G is in contact with the pixel electrode 23G at the position P2 of the substrate 10 in the normal line direction A1, and electrically couples the pixel electrode 23G and the reflection layer 21G to each other. The position P2 is the upper surface of the conductive portion 4G. The conductive portion 4B is a contact plug that has conductivity and fills a through hole passing through the optical adjustment layer 22B. The conductive portion 4B is in contact with the pixel electrode 23B at the position P3 of the substrate 10 in the normal line direction A1, and electrically couples the pixel electrode 23B and the reflection layer 21B to each other. The position P3 is the upper surface of the conductive portion 4B.

Further, as described above, examples of the material of the conductive portions 4R, 4G, and 4B include metals such as tungsten, titanium, chromium, iron, and aluminum, metal nitride, metal silicide, and the like. Among them, the conductive portions 4R, 4G, and 4B may contain tungsten. Among those metals, tungsten has an excellent filling property. Thus, the through hole having a high aspect ratio can be filled evenly by using tungsten.

Each of the conductive portions 4R, 4G, and 4B may be configured by a single material, or may be formed of a plurality of layers. For example, each of the conductive portions 4R, 4G, and 4B includes a barrier layer and a conductive layer. The barrier layer is in contact with an inner wall surface forming the through hole. The barrier layer is provided to prevent diffusion of the components of the conductive layer. The conductive layer is arranged on the inner side of the barrier layer, and fills the through hole. The barrier layer may contain tungsten nitride (WN) or titanium nitride (TiN). The conductive layer may contain tungsten.

The pixel electrode 23R, the pixel electrode 23G, and the pixel electrode 23B are arranged at the optical adjustment unit 22 for each of the pixels P. Each of the pixel electrode 23R, the pixel electrode 23G, and the pixel electrode 23B has a light transmissive property. Each of the pixel electrode 23R, the pixel electrode 23G, and the pixel electrode 23B is provided between the first electrode 25 and the substrate 10, and faces the first electrode 25. Further, examples of the material of each of the pixel electrode 23R, the pixel electrode 23G, and the pixel electrode 23B include a transparent conductive material such as Indium Tin Oxide (ITO) and Indium Zinc Oxide (IZO). For example, the thickness of each of the pixel electrode 23R, the pixel electrode 23G, and the pixel electrode 23B is 10 nm or more and 30 nm or less.

At the pixel electrode 23R, the pixel electrode 23G, and the pixel electrode 23B, the element separation layer 27 is arranged. The element separation layer 27 includes three openings corresponding to the pixel electrode 23R, the pixel electrode 23G, and the pixel electrode 23B, for each of the pixels P. The three openings form the light emission regions AR, AG, and AB in FIG. 3. Note that each of the openings is a hole formed in the element separation layer 27. Further, the element separation layer 27 insulates the pixel electrode 23R, the pixel electrode 23G, and the pixel electrode 23B from one another. The element separation layer 27 is provided to securely separate the sub pixels PR, PG, and PB. Thus, vividness of each color can be improved. Examples of the material of the element separation layer 27 include an inorganic silicon material such as silicon oxide and silicon nitride. The thickness of the element separation layer 27 is 10 nm or more and 40 nm or less, for example.

The light emission function layer 24 is arranged at the pixel electrode 23R, the pixel electrode 23G, the pixel electrode 23B, and the element separation layer 27. The light emission function layer 24 is provided between the first electrode 25 and the pixel electrode 23R, between the first electrode 25 and the pixel electrode 23G, and between the first electrode 25 and the pixel electrode 23B. The light emission function layer 24 includes a light-emitting layer containing an organic light-emitting material. The organic light-emitting material is a light-emitting organic compound. Further, for example, the light emission function layer 24 includes a hole injection layer, a hole transport layer, an electron transport layer, an electron injection layer, and the like, in addition to the light-emitting layer. The light emission function layer 24 realizes white light emission by including the light-emitting layer in which each emission color of blue, green, and red is obtained. Note that the configuration of the light emission function layer 24 is not limited to the above-mentioned configuration, and a publicly known configuration may be applied thereto.

The first electrode 25 is arranged at the light emission function layer 24. The first electrode 25 has a semi-transmissive property, and has a light-reflecting property and a light transmissive property. The first electrode 25 contains a metal material containing an alloy containing Ag such as MgAg.

The sealing layer 26 is arranged at the first electrode 25. The sealing layer 26 has a gas barrier property, and protects the portions below the sealing layer 26 from moisture, oxygen, or the like. Further, the sealing layer 26 is a flattening layer for providing a flat surface at the upper surface. For example, the sealing layer 26 is configured by a lamination body of a plurality of sealing films. Each of the sealing films contains an organic material containing silicon such as silicon nitride and silicon oxynitride or a resin such as an epoxy resin.

The light-emitting element 20R includes the reflection layer 21R, the optical adjustment layer 22R, the pixel electrode 23R, the light emission function layer 24, and the first electrode 25. The light-emitting element 20G includes the reflection layer 21G, the optical adjustment layer 22G, the pixel electrode 23G, the light emission function layer 24, and the first electrode 25. The light-emitting element 20B includes the reflection layer 21B, the optical adjustment layer 22B, the pixel electrode 23B, the light emission function layer 24, and the first electrode 25.

Further, the light-emitting element 20R includes the optical resonator structure 29R. The optical resonator structure 29R resonates light in the red wavelength range between the reflection layer 21R and the first electrode 25. Specifically, light generated in the light emission function layer 24 is multi-reflected between the reflection layer 21R and the first electrode 25 to selectively intensify light in the red wavelength range. The light-emitting element 20G includes an optical resonator structure 29G. The optical resonator structure 29G resonates light in the green wavelength range between the reflection layer 21G and the first electrode 25. Specifically, light generated in the light emission function layer 24 is multi-reflected between the reflection layer 21G and the first electrode 25 to selectively intensify light in the green wavelength range. The light-emitting element 20B includes an optical resonator structure 29B. The optical resonator structure 29B resonates light in the blue wavelength range between the reflection layer 21B and the first electrode 25. Specifically, light generated in the light emission function layer 24 is multi-reflected between the reflection layer 21B and the first electrode 25 to selectively intensify light in the blue wavelength range.

When a resonance wavelength of each of the optical resonator structures 29R, 29G, and 29B is λ0, a relationship expression [1] given below is satisfied. Note that ϕ (radian) in the relationship expression [1] indicates a total of a phase shift generated by transmission and reflection between the reflection layer 21R, 21G, or 21B and the first electrode 25.

$$\{ ( 2 \times L Θ ) / λ Θ + Φ \} / ( 2 π ) = m Θ ( m Θ is an integer ) \qquad [ 1 ]$$

The optical distances LR, LG, and LB are set so that a peak wavelength of light in a wavelength range to be extracted is the wavelength λ0. Through the setting, light in the wavelength range to be extracted is intensified, and high intensification of the light and reduction of a spectrum can be achieved.

The coloring layer 5 is arranged at the sealing layer 26. The coloring layer 5 is a color filter that selectively transmits light in a predetermined wavelength range. The predetermined wavelength range includes the peak wavelength λ0 for each color. By providing the coloring layer 5, color purity of the light emitted from each of the sub pixels P0 can be improved, as compared to a case in which the coloring layer 5 is not provided. The coloring layer 5 is configured by, for example, a resin material such as an acrylic photosensitive resin material containing a coloring material. The coloring material is a pigment or a dye.

The coloring layer 5 includes a colored portion 51R, a colored portion 51G, and a colored portion 51B. The colored portion 51R is provided corresponding to the sub pixel PR and selectively transmits the light in the red wavelength range among the light from the light-emitting element 20R. The colored portion 51G is provided corresponding to the sub pixel PG and selectively transmits the light in the green wavelength range among the light from the light-emitting element 20G. The colored portion 51B is provided corresponding to the sub pixel PB and selectively transmits the light in the blue wavelength range among the light from the light-emitting element 20B.

The light-transmitting substrate 9 is bonded to the element substrate 1 described above via the adhesive layer 90. The adhesive layer 90 is, for example, a transparent adhesive using a resin material such as an epoxy resin or an acrylic resin. The light-transmitting substrate 9 is a cover that protects the element substrate 1. The light-transmitting substrate 9 is formed of, for example, a glass substrate or a quartz substrate.

### 1E. Resonator Structure and Conductive Portion

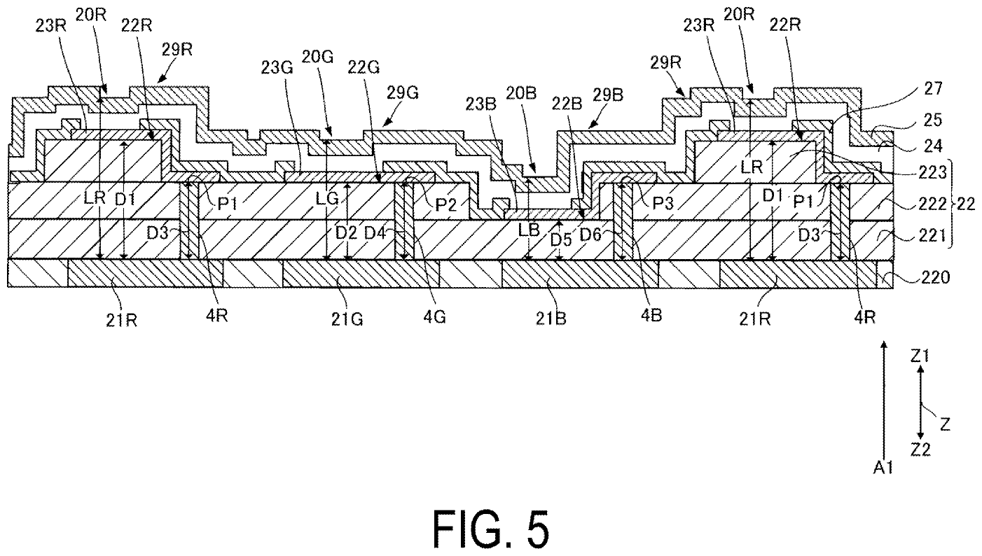

FIG. 5 is a view illustrating a part of the electro-optical device 100 illustrated in FIG. 4. As described above, the light-emitting element 20R includes the optical resonator structure 29R. The light-emitting element 20G includes the optical resonator structure 29G. The light-emitting element 20B includes the optical resonator structure 29B.

A resonant wavelength of the optical resonator structure 29R is determined based on the optical distance LR. A resonant wavelength of the optical resonator structure 29G is determined based on the optical distance LG. A resonant wavelength of the optical resonator structure 29B is determined based on the optical distance LB. The optical adjustment layer 22R is provided to adjust the optical distance LR. The optical adjustment layer 22G is provided to adjust the optical distance LG. The optical adjustment layer 22B is provided to adjust the optical distance LB.

The resonant wavelength differs for each color. Thus, the optical distances LR, LG, and LB are different from one another. Specifically, the optical distances LR, LG, and LB are longer in the stater order. Therefore, the thicknesses of the optical adjustment layers 22R, 22G, and 22B in the Z1 direction are larger in the stated order. Therefore, the distance D1 is larger than the distance D2, and the distance D2 is larger than the distance D5. The distance D1 is a distance between the light emission region AR of the pixel electrode 23R and the reflection layer 21R. The distance D2 is a distance between the light emission region AG of the pixel electrode 23G and the reflection layer 21G. The distance D5 is a distance between the light emission region AB of the pixel electrode 23B and the reflection layer 21R.

Further, the conductive portion 4R is in contact with the pixel electrode 23R at the position P1. The conductive portion 4G is in contact with the pixel electrode 23G at the position P2. The conductive portion 4B is in contact with the pixel electrode 23B at the position P3.

The distance between the reflection layer 21R and the position P1 in the normal line direction A1 is the distance D3. Further, the distance between the reflection layer 21G and the position P2 in the normal line direction A1 is the distance D4. The distance between the reflection layer 21B and the position P3 in the normal line direction A1 is the distance D6.

In the present embodiment, the difference between the distance D3 and the distance D4 is smaller than the difference between the distance D1 and the distance D2 that are described above. Moreover, the difference between the distance D4 and the distance D6 is smaller than the difference between the distance D2 and the distance D5 that are described above. The difference between the distance D3 and the distance D4 and the difference between the distance D4 and the distance D6 are smaller than the difference between the distance D1 and the distance D2 and the difference between the distance D2 and the distance D5. Thus, the difference between the positions P1, P2, and P3 in the normal line direction A1 can be reduced. In other words, a difference between the respective upper surfaces of the conductive portions 4R, 4G, and 4B in height can be reduced. Thus, a step between the respective upper surfaces of the conductive portions 4R, 4G, and 4B arrayed in the X1 direction, which are illustrated in FIG. 3, can be reduced. Further, a step between the upper layer portions of the conductive portions 4R, 4G, and 4B can be reduced. Therefore, stray light that may be generated when light hits a step between the conductive portions 4R, 4G, and 4B can be suppressed more than the related art. Therefore, degradation of display quality of the electro-optical device 100 can be suppressed more than the related art.

Further, the optical resonator structures 29R, 29G, and 29B are provided. Thus, purity of light of each color can be improved. In contrast, in the relater art, stray light due to a step between the conductive portions 4R, 4G, and 4B is disadvantageously generated. According to the present embodiment, purity of light of each color can be improved, and stray light due to a step can also be suppressed. Thus, display quality of the electro-optical device 100 can be improved.

In the illustrated example, the distance D3, the distance D4, and the distance D6 are equal to one another. Thus, a step between the respective upper surfaces of the conductive portions 4R, 4G, and 4B can be eliminated. Further, a step between the upper layer portions of the conductive portions 4R, 4G, and 4B can be reduced. Therefore, stray light that may be generated when light hits a step between the conductive portions 4R, 4G, and 4B can be suppressed more effectively than the related art.

Further, the distance D3, the distance D4, and the distance D6 are equal to one another. Thus, those distance are easily formed in a collective manner in the same step. Thus, the yield of the conductive portions 4R, 4G, and 4B can be improved. Thus, quality reliability of the electro-optical device 100 can be increased.

Further, each of the conductive portions 4R, 4G, and 4B is a contact plug. Thus, irregularities are less likely to be generated at each of the upper surfaces of the conductive portions 4R, 4G, and 4B. Thus, as compared to a case in which each of the conductive portions 4R, 4G, and 4B is a so-called trench-type electrode, irregularities due to the conductive portions 4R, 4G, and 4B can be suppressed. Note that each of the conductive portions 4R, 4G, and 4B may be a so-called trench-type electrode.

Further, the difference between the distance D3 and the distance D2 is smaller than the difference between the distance D1 and the distance D2. Thus, the distance D3 can be closer to the distance D2 with respect to the distance D1. Moreover, the difference between the distance D2 and the distance D6 is smaller than the difference between the distance D2 and the distance D5. Thus, the distance D6 can be closer to the distance D2 with respect to the distance D5. Further, the difference between the distance D2 and the distance D4 is smaller than the difference between the distance D1 and the distance D3 and the difference between the distance D6 and the distance D5. Thus, the distances D3, D4, and D6 can be closer to the distance D2. The distance D2 has a size between the distance D1 and the distance D5, and corresponds to the sub pixel PG. The distances D3, D4, and D6 are closer to the distance D2. With this, a step due to the conductive portions 4R, 4G, and 4B can be suppressed particularly effectively.

In the illustrated example, each of the distances D3, D4, and D6 is equal to the distance D2. Therefore, the lengths of the conductive portions 4R, 4G, and 4B in the normal line direction A1 are equal to the distance D2. The conductive portions 4R, 4G, and 4B correspond to the distance D2, and correspond to the green sub pixel PG. The distances D2, D3, D4, and D6 are equal to one another. Thus, in the example illustrated in FIG. 3, a step between a portion overlapping with the conductive portion 4R of the pixel electrode 23R in plan view, a portion overlapping with the conductive portion 4G of the pixel electrode 23G in plan view, a portion overlapping with the conductive portion 4B of the pixel electrode 23B in plan view, and the light emission region AG of the pixel electrode 23G is eliminated. The distances D2, D3, D4, and D5 are equal to one another. With this, a step due to the conductive portions 4R, 4G, and 4B can be suppressed most effectively.

Further, as described above, in the present embodiment, the arrangement of the sub pixels P0 is the stripe arrangement. Thus, as illustrated in FIG. 3, the sub pixels PR, PG, and PB are arrayed in the X1 direction. Therefore, the pixel electrodes 23R, 23G, and 23B are arrayed in the X1 direction. Further, the conductive portions 4R, 4G, and 4B are arrayed in the X1 direction. Thus, the positions P1, P2, and P3 are arrayed in the X1 direction.

As described above, when the positions P1, P2, and P3 are arrayed in the X1 direction, in other words, the respective upper surfaces of the conductive portions 4R, 4G, and 4B are arrayed in the X1 direction, an effect of reducing a step between the respective upper surfaces of the conductive portions 4R, 4G, and 4B is exerted in a significantly effective manner. Thus, an effect of reducing a step between the upper layer portions of the conductive portion 4R, the conductive portion 4G, and the conductive portion 4B is exerted in a significantly effective manner.

### 2. Modification Examples

The embodiment exemplified above may be modified in various ways. Specific modified aspects that may be applied to the above-described embodiment are exemplified below.

### 2-1. First Modification Example

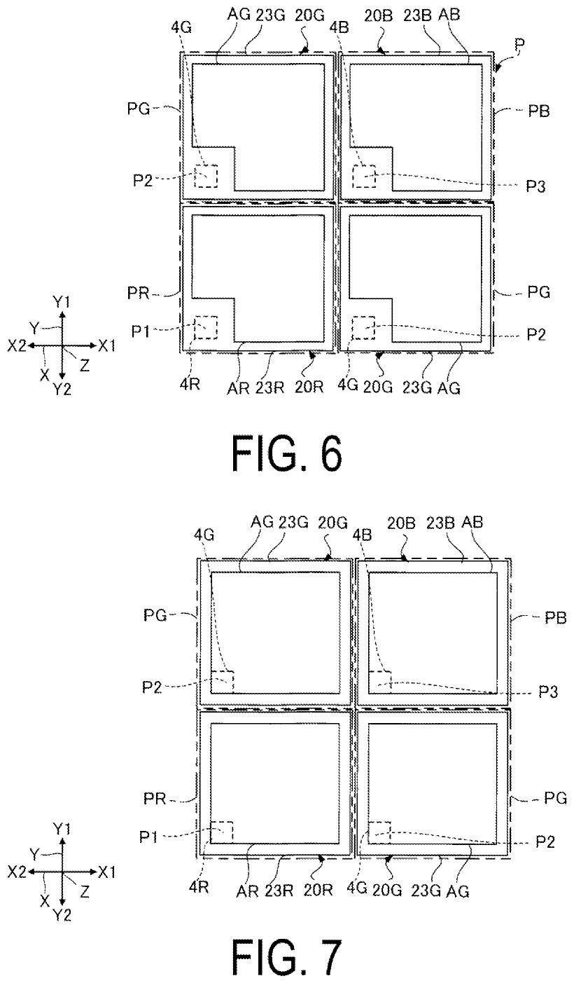

FIG. 6 is a plan view of one pixel P in a first modification example. In the example illustrated in FIG. 6, the arrangement of the sub pixels P0 is the Bayer arrangement. In the example illustrated in FIG. 6, one pixel P includes two sub pixels PG. One sub pixel PG and the sub pixel PB are arrayed in the X1 direction. The one sub pixel PG and the sub pixel PR are arrayed in the Y2 direction. Further, one sub pixel PG and another sub pixel PG are arrayed in a direction intersecting the X1 direction and the Y1 direction in plan view.

In plan view, the pixel electrode 23B is arrayed in the X1 direction with respect to the pixel electrode 23G arranged obliquely upward to the left in FIG. 6. The pixel electrode 23R is arrayed in the Y2 direction with respect to the pixel electrode 23G. Further, the pixel electrode 23G arranged obliquely downward to the right in FIG. 6 is arrayed in the direction intersecting the X1 direction and the Y1 direction in plan view with respect to the pixel electrode 23G arranged obliquely upward to the left in FIG. 6.

The conductive portion 4R is arranged obliquely downward to the left of the pixel electrode 23R in the drawing. The conductive portion 4G is arranged obliquely downward to the left of the pixel electrode 23G in the drawing. The conductive portion 4B is arranged obliquely downward to the left of the pixel electrode 23B in the drawing. Further, in plan view, the light emission region AR is provided at a position different from the conductive portion 4R, and does not overlap with the conductive portion 4R. In plan view, the light emission region AG is provided at a position different from the conductive portion 4G, and does not overlap with the conductive portion 4G. In plan view, the light emission region AB is provided at a position different from the conductive portion 4B, and does not overlap with the conductive portion 4B.

In plan view, the smallest distance between the light emission region AR and the conductive portion 4B is smaller than the smallest distance between the light emission region AR and the light emission region AB. Thus, in plan view, the distance between the light emission region AR and the position P3 is smaller than the distance between the light emission region AR and the light emission region AB. In this case, the distances D3, D4, and D6 correspond to the distance D2 of the sub pixel PG. As a result, a step between the light emission region AR and a portion of the pixel electrode 23B, which overlaps with the conductive portion 4B in plan view, can be reduced. Thus, generation of stray light due to a step in the conductive portion 4B can be suppressed.

### 2-2. Second Modification Example

FIG. 7 is a plan view of one pixel P in a second modification example. In the second modification example, a difference from the first modification example is described. In the second modification example illustrated in FIG. 7, in plan view, the conductive portion 4R is provided in the light emission region AR, and overlaps with the light emission region AR. In plan view, the conductive portion 4G is provided in the light emission region AG, and overlaps with the light emission region AG. In plan view, the conductive portion 4B is provided in the light emission region AB, and overlaps with the light emission region AB.

In the second modification example, for example, a step between the light emission region AR and a portion of the pixel electrode 23B, which overlaps with the conductive portion 4B in plan view, can be reduced. Thus, generation of stray light due to a step in the conductive portion 4B can be suppressed.

### 2-3. Third Modification Example

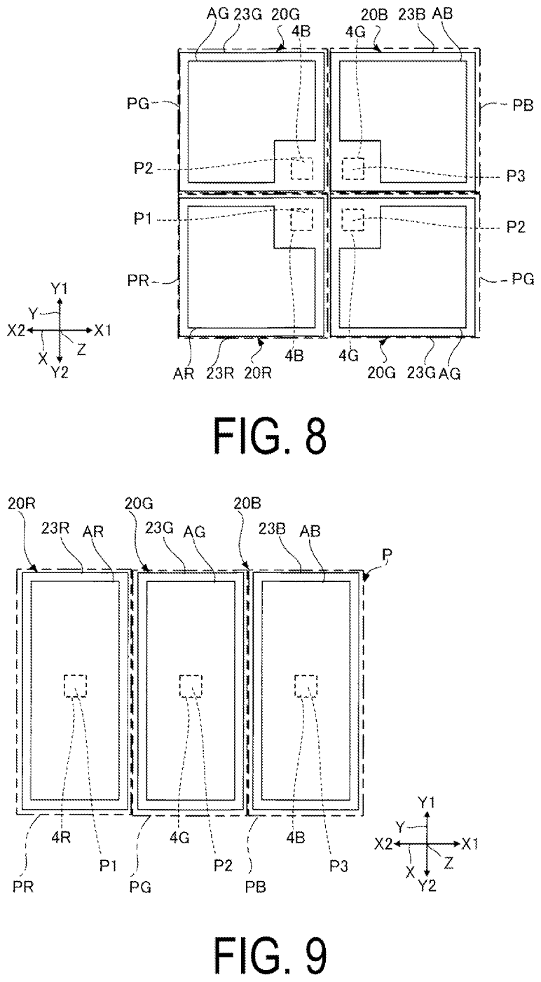

FIG. 8 is a plan view of one pixel P in a third modification example. In the third modification example, a difference from the first modification example is described. In the third modification example illustrated in FIG. 8, the conductive portion 4R, the two conductive portions 4G, and the conductive portion 4B are gathered at the center portion of one pixel P in plan view. Thus, the smallest distance between the position P1 and the position P3 is smaller than the smallest distance between the light emission region AR and the light emission region AB.

The conductive portion 4R, the two conductive portions 4G, and the conductive portion 4B are gathered at the center portion of one pixel P in plan view. Thus, similarly to the embodiment, an effect of reducing a step between the upper layer portions of the conductive portion 4R, the two conductive portions 4G, and the conductive portion 4B is exerted in a significantly effective manner. Thus, an effect of reducing a step between the upper layer portions of the conductive portion 4R, the two conductive portions 4G, and the conductive portion 4B is exerted in a significantly effective manner.

### 2-4. Fourth Modification Example

FIG. 9 is a plan view of one pixel P in a fourth modification example. The arrangement of the sub pixels P0 illustrated in FIG. 9 is the stripe arrangement. As illustrated in FIG. 9, in plan view, the conductive portion 4R may be provided in the light emission region AR, and may overlap with the light emission region AR. In plan view, the conductive portion 4G may be provided in the light emission region AG, and may overlap with the light emission region AG. In plan view, the conductive portion 4B may be provided in the light emission region AB, and may overlap with the light emission region AB.

### 2-5. Other Modification Examples

In the above-described embodiment, one pixel P includes the sub pixels PR, PG, and PB. However, one pixel P may include any two of the sub pixels PR, PG, and PB, and the remaining one of them may be omitted. In this case, the “fourth electrode”, the “third reflection layer”, the “third optical adjustment layer”, the “third driving circuit”, the “third light emission region”, the “third position”, the “fifth distance”, and the “sixth distance”are omitted.

For example, when one pixel P includes the sub pixels PR and PB, the following case is achieved. The pixel electrode 23R corresponds to the “second electrode”, and the pixel electrode 23B corresponds to the “third electrode”. The reflection layer 21R corresponds to the “first reflection layer”, and the reflection layer 21B corresponds to the “second reflection layer”. The optical adjustment layer 22R corresponds to the “first optical adjustment layer”, and the optical adjustment layer 22B corresponds to the “second optical adjustment layer”. The driving circuit 30R corresponds to the “first driving circuit”, and the driving circuit 30B corresponds to the “second driving circuit”. The conductive portion 4R corresponds to the “first conductive portion”, and the conductive portion 4B corresponds to the “second conductive portion”. The light emission region AR corresponds to the “first light emission region”, and the light emission region AB corresponds to the “second light emission region”. The position P1 corresponds to the “first position”, and the position P3 corresponds to the “second position”. The distance D1 corresponds to the “first distance”, the distance D5 corresponds to the “second distance”, the distance D3 corresponds to the “third distance”, and the distance D6 corresponds to the “fourth distance”. The “first wavelength range” corresponds to the red wavelength range, and the “second wavelength range” corresponds to the blue wavelength range.

For example, when one pixel P includes the sub pixels PG and PB, the following case is achieved. The pixel electrode 23G corresponds to the “second electrode”, and the pixel electrode 23B corresponds to the “third electrode”. The reflection layer 21G corresponds to the “first reflection layer”, and the reflection layer 21B corresponds to the “second reflection layer”. The optical adjustment layer 22G corresponds to the “first optical adjustment layer”, and the optical adjustment layer 22B corresponds to the “second optical adjustment layer”. The driving circuit 30G corresponds to the “first driving circuit”, and the driving circuit 30B corresponds to the “second driving circuit”. The conductive portion 4G corresponds to the “first conductive portion”, and the conductive portion 4B corresponds to the “second conductive portion”. The light emission region AG corresponds to the “first light emission region”, and the light emission region AB corresponds to the “second light emission region”. The position P2 corresponds to the “first position”, and the position P3 corresponds to the “second position”. The distance D2 corresponds to the “first distance”, the distance D5 corresponds to the “second distance”, the distance D4 corresponds to the “third distance”, and the distance D6 corresponds to the “fourth distance”. The “first wavelength range” corresponds to the green wavelength range, and the “second wavelength range” corresponds to the blue wavelength range.

Further, the arrangement of the sub pixels P0 is not limited to the stripe arrangement and the Bayer arrangement, and may be other types of arrangement such as the rectangle arrangement and the delta arrangement.

### 3. Electronic Apparatus

The electro-optical device 100 according to the above-described embodiment is applicable to various electronic apparatuses.

### 3-1. Head-Mounted Display

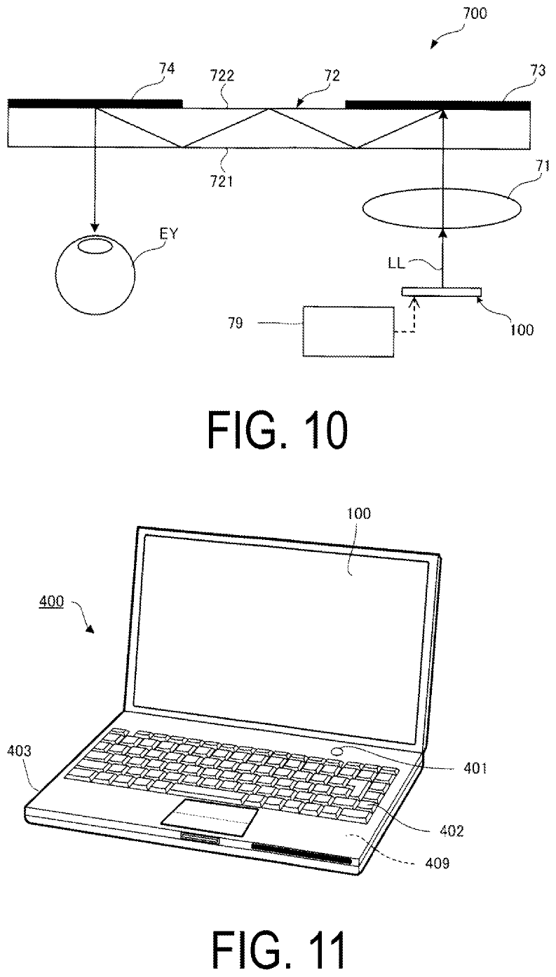

FIG. 10 is a plan view schematically illustrating a part of a virtual image electro-optical device 700 as an example of an electronic apparatus. The virtual image electro-optical device 700 illustrated in FIG. 10 is a head-mounted display (HMD) worn on a head of an observer to display images. The virtual image electro-optical device 700 includes the electro-optical device 100 described above, a collimator 71, a light guide 72, a first reflection-type volume hologram 73, a second reflection-type volume hologram 74, and a control unit 79. Note that light emitted from the electro-optical device 100 is emitted as image light LL.

The control unit 79 includes, for example, a processor and a memory, and controls the operation of the electro-optical device 100. The collimator 71 is arranged between the electro-optical device 100 and the light guide 72. The collimator 71 collimates light emitted from the electro-optical device 100. The collimator 71 is constituted by a collimating lens or the like. The light collimated by the collimator 71 is incident on the light guide 72.

The light guide 72 has a flat plate shape and is arranged extending in a direction intersecting a direction of light incident via the collimator 71. The light guide 72 reflects and guides light therein. A light incident port on which light is incident and a light emission port from which light is emitted are provided in a surface 721 of the light guide 72 facing the collimator 71. The first reflection-type volume hologram 73 as a diffractive optical element and the second reflection-type volume hologram 74 as a diffractive optical element are arranged at a surface 722 of the light guide 72 opposite to the surface 721. The second reflection-type volume hologram 74 is provided closer to the light emission port side than the first reflection-type volume hologram 73. The first reflection-type volume hologram 73 and the second reflection-type volume hologram 74 have interference fringes corresponding to a predetermined wavelength range, and diffract and reflect light in the predetermined wavelength range.

In the virtual image electro-optical device 700 having such a configuration, the image light LL incident on the light guide 72 through the light incidence port travels while being repeatedly reflected, and is guided from the light emission port to an eye EY of the observer, and thus the observer can observe an image formed as a virtual image formed by the image light LL.

The virtual image electro-optical device 700 includes the above-described electro-optical device 100. The electro-optical device describes above has satisfactory display quality. Therefore, by including the electro-optical device 100, the virtual image electro-optical device 700 with high display quality can be provided.

Note that the virtual display apparatus 700 may include a synthetic element such as a dichroic prism configured to synthesize light emitted from the electro-optical device 100. In this case, the virtual display apparatus 700 may include, for example, the electro-optical device 100 configured to emit light in the blue wavelength range, the electro-optical device 100 configured to emit light in the green wavelength range, and the electro-optical device 100 configured to emit light in the red wavelength range.

### 3-2. Personal Computer

FIG. 11 is a perspective view illustrating a personal computer 400 as an example of the electronic apparatus according to the present disclosure. The personal computer 400 illustrated in FIG. 11 includes the electro-optical device 100, and a main body unit 403 provided with a power switch 401 and a keyboard 402, and a control unit 409. The control unit 409 includes, for example, a processor and a memory, and controls the operation of the electro-optical device 100. The personal computer 400 includes the above-described electro-optical device 100, and thus has excellent quality.

Note that examples of the “electronic apparatus” including the electro-optical device 100 include, in addition to the virtual image electro-optical device 700 illustrated in FIG. 10 and the personal computer 400 illustrated in FIG. 11, apparatuses arranged close to eyes such as a digital scope, a digital binocular, a digital still camera, and a video camera. Further, the “electronic apparatus” including the electro-optical device 100 is applied as a mobile phone, a smartphone, a personal digital assistant (PDA), a car navigation device, and a vehicle-mounted display unit. Furthermore, the “electronic apparatus” including the electro-optical device 100 is applied as illumination for illuminating light.

The present disclosure is described above based on the illustrated embodiment. However, the present disclosure is not limited thereto. In addition, the configuration of each part of the present disclosure may be replaced with any configuration that exhibits the same function as in the embodiment described above, or any configuration can be added. Further, any configuration may be combined with each other in the above-described embodiments of the present disclosure.

What is claimed is:

1. An electro-optical device comprising:
a substrate;
a first electrode having a semi-transmissive property;
a second electrode having a light transmissive property, being provided between the first electrode and the substrate, and facing the first electrode;
a third electrode having a light transmissive property, being provided between the first electrode and the substrate, and facing the first electrode;
a first reflection layer being provided between the substrate and the second electrode and facing the second electrode;
a second reflection layer being provided between the substrate and the third electrode and facing the third electrode;
a light emission function layer being provided between the first electrode and the second electrode and between the first electrode and the third electrode;
a first optical adjustment layer being provided between the second electrode and the first reflection layer;
a second optical adjustment layer being provided between the third electrode and the second reflection layer;
a first driving circuit being provided at the substrate and being configured to control a current amount supplied to the second electrode;
a second driving circuit being provided at the substrate and being configured to control a current amount supplied to the third electrode;
a first conductive portion being in contact with the second electrode at a first position of the substrate in a normal line direction and being configured to electrically couple the second electrode and the first reflection layer; and
a second conductive portion being in contact with the third electrode at a second position in the normal line direction and being configured to electrically couple the third electrode and the second reflection layer, wherein
the second electrode includes a first light emission region through which light in a first wavelength range passes,
the third electrode includes a second light emission region through which light in a second wavelength range passes,
a first distance is larger than a second distance, and a difference between a third distance and a fourth distance is smaller than a difference between the first distance and the second distance, the first distance being a distance between the first light emission region of the second electrode and the first reflection layer in the normal line direction, the second distance being a distance between the second light emission region of the third electrode and the second reflection layer in the normal line direction, the third distance being a distance between the first reflection layer and the first position in the normal line direction, the fourth distance being a distance between the second reflection layer and the second position in the normal line direction.

2. The electro-optical device according to claim 1, wherein
each of the first conductive portion and the second conductive portion is a contact plug.

3. The electro-optical device according to claim 1, comprising:
a fourth electrode having a light transmissive property, being provided between the first electrode and the substrate, and facing the first electrode;
a third reflection layer being provided between the substrate and the fourth electrode and facing the fourth electrode;
a third optical adjustment layer being provided between the fourth electrode and the third reflection layer;
a third driving circuit being provided at the substrate and being configured to control a current amount supplied to the fourth electrode; and
a third conductive portion being in contact with the fourth electrode at a third position in the normal line direction and being configured to electrically couple the fourth electrode and the third reflection layer, wherein
the light emission function layer is provided between the first electrode and the fourth electrode,
the fourth electrode includes a third light emission region through which light in a third wavelength range passes, and
the second distance is larger than a fifth distance, and a difference between the fourth distance and a sixth distance is smaller than a difference between the second distance and the fifth distance, the fifth distance being a distance between the third light emission region of the fourth electrode and the third reflection layer in the normal line direction, the sixth distance being a distance between the third reflection layer and the third position in the normal line direction.

4. The electro-optical device according to claim 3, wherein
a difference between the third distance and the second distance is smaller than a difference between the first distance and the second distance, and
a difference between the second distance and the sixth distance is smaller than a difference between the second distance and the fifth distance.

5. The electro-optical device according to claim 3, wherein
the second electrode, the third electrode, and the fourth electrode are arrayed in a first direction intersecting the normal line direction, and
the first position, the second position, and the third position are arrayed in the first direction.

6. The electro-optical device according to claim 4, wherein
the fourth electrode is arrayed in a first direction with respect to the third electrode, the first direction intersecting the normal line direction,
the second electrode is arrayed in a second direction with respect to the third electrode, the second direction intersecting the normal line direction and the first direction, and
a distance between the first light emission region and the third position is smaller than a distance between the first light emission region and the third light emission region in plan view.

7. The electro-optical device according to claim 3, wherein
the fourth electrode is arrayed in a first direction with respect to the third electrode, the first direction intersecting the normal line direction,
the second electrode is arrayed in a second direction with respect to the third electrode, the second direction intersecting the normal line direction and the first direction, and
a distance between the first position and the third position is smaller than a distance between the first light emission region and the third light emission region.

8. An electronic apparatus comprising:
the electro-optical device according to claim 1; and
a control unit configured to control operation of the electro-optical device.
